(19) United States
(12) Patent Application Publication
(10) Pub. No.: US 2026/0086158 A1
(43) Pub. Date: Mar. 26, 2026

(54) ANOMALY DETECTION OF FAULTY BATTERY CELLS USING PHYSICAL FEATURES

(71) Applicant: GM Global Technology Operations LLC, Detroit, MI (US)

(72) Inventors: Shahar Dror, Tel-Aviv (IL); Ram Machlev, Tel-Aviv (IL); Niles Fleischer, Rehovot (IL)

(73) Assignee: GM Global Technology Operations LLC, Detroit, MI (US)

(21) Appl. No.: 18/893,318

(22) Filed: Sep. 23, 2024

(51) Int. Cl. G01R 31/382; G01R 31/36; G01R 31/367

(52) U.S. Cl. CPC G01R 31/382; G01R 31/3646; G01R 31/3648; G01R 31/367

(57) ABSTRACT

A method includes determining an operating parameter corresponding to each cell of a plurality of cells of a rechargeable battery based on processing of sensor data representative of operation of the rechargeable battery. During operation of the rechargeable battery, and based on determining a change in a distribution of the operating parameters corresponding to the plurality of cells, the method includes determining a dynamic threshold value. Based on the operating parameter corresponding to one or more cells of the plurality of cells violating the dynamic threshold value, the method includes classifying the one or more cells of the plurality of cells as a faulty cell. The method includes generating an alert representative of the one or more cells of the plurality of cells classified as the faulty cell.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates generally to fault detection for rechargeable battery packs. Typically, a system determines the operating health of a rechargeable battery pack based on signals and sensor readings like the voltage of the battery pack, the operating temperature of the battery pack, current in or out of the battery pack, and the like. These signals are compared to static threshold values or ranges of allowed values and, when the signal violates the static threshold value or is outside the range of allowed values, the system identifies the battery pack as compromised. That is, the health of the rechargeable battery pack is generally determined based on comparing operating parameters of the battery to static thresholds that are preset or predefined values that do not change during battery operation or over the life of the battery. Commonly, the operating health of the battery pack is compromised when one or more cells of the battery pack are defective. Early and accurate detection of defective battery cells is imperative to avoid further failure, such as damage to additional battery cells or to a vehicle powered by the battery pack.

However, because the battery operating signals are compared to static threshold values or ranges of allowed values, typical approaches often result in inaccurate detection of battery faults. That is, some battery faults may go undetected, such as when operating parameters of the battery pack fail to represent compromised health of individual cells of the battery pack. Further, when battery operation is degraded uniformly across the cells of the battery pack (e.g., due to extreme hot or cold environmental temperatures), the system may identify a battery fault even though no individual cell is compromised.

### SUMMARY

One aspect of the disclosure provides a computer-implemented method that when executed on data processing hardware causes the data processing hardware to perform operations. The operations include, based on processing of sensor data representative of operation of a rechargeable battery, determining an operating parameter corresponding to each cell of a plurality of cells of the rechargeable battery. During operation of the rechargeable battery, and based on determining a change in a distribution of the operating parameters corresponding to the plurality of cells, the operations include determining a dynamic threshold value. Based on the operating parameter corresponding to one or more cells of the plurality of cells violating the dynamic threshold value, the operations include classifying the one or more cells of the plurality of cells as a faulty cell. The operations include generating an alert representative of the one or more cells of the plurality of cells classified as the faulty cell.

Implementations of the disclosure may include one or more of the following optional features. In some implementations, the sensor data is representative of at least one of a current of the rechargeable battery and respective voltages for each cell of the plurality of cells.

In some examples, the operating parameter corresponding to each cell is determined based on an electric circuit model (ECM). In further examples, the ECM includes at least one resistance value for the cell and at least one capacitance value for the cell.

In some aspects, the distribution of the operating parameters corresponding to the plurality of cells includes a plurality of quantiles. Each quantile of the plurality of quantiles includes a respective set of operating parameters and has a respective width between indices of the set of operating parameters. In further aspects, based on determining that the width of an edge quantile of the plurality of quantiles has increased by more than the widths of other quantiles of the plurality of quantiles, the dynamic threshold value is one of (i) an intra-quantile threshold value between a pair of adjacent operating parameters of the set of parameters within the edge quantile that have the largest difference compared to other pairs of adjacent operating parameters of the set of parameters within the edge quantile and (ii) an inter-quantile threshold value between adjacent operating parameters of the set of parameters within the edge quantile and the set of parameters within an adjacent quantile adjacent to the edge quantile. In other further aspects, based on determining that the width of an intermediate quantile of the plurality of quantiles has increased by more than the widths of other quantiles of the plurality of quantiles, the dynamic threshold value includes a first value between a first pair of adjacent operating parameters and a second value between a second pair of adjacent operating parameters. The first pair of adjacent operating parameters of the set of parameters have the largest difference compared to other pairs of adjacent operating parameters of the set of parameters. The second pair of adjacent operating parameters of the set of parameters have the second largest difference compared to other pairs of adjacent operating parameters of the set of parameters.

In some implementations, operation of the rechargeable battery includes at least one of charging of the rechargeable battery and discharging of the rechargeable battery. The rechargeable battery may be a lithium-ion battery. Optionally, the rechargeable battery is equipped at a vehicle.

Another aspect of the disclosure provides a system. The system includes memory hardware storing instructions that, when executed on data processing hardware in communication with the memory hardware, cause the data processing hardware to perform operations. The operations include, based on processing of sensor data representative of operation of a rechargeable battery, determining an operating parameter corresponding to each cell of a plurality of cells of the rechargeable battery. During operation of the rechargeable battery, and based on determining a change in a distribution of the operating parameters corresponding to the plurality of cells, the operations include determining a dynamic threshold value. Based on the operating parameter corresponding to one or more cells of the plurality of cells violating the dynamic threshold value, the operations include classifying the one or more cells of the plurality of cells as a faulty cell. The operations include generating an alert representative of the one or more cells of the plurality of cells classified as the faulty cell. This aspect may include one or more of the following optional features.

In some implementations, the sensor data is representative of at least one of a current of the rechargeable battery and respective voltages for each cell of the plurality of cells. In some examples, the operating parameter corresponding to each cell is determined based on an electric circuit model (ECM). The ECM includes at least one resistance value for the cell and at least one capacitance value for the cell.

In some aspects, the distribution of the operating parameters corresponding to the plurality of cells includes a plurality of quantiles. Each quantile of the plurality of quantiles includes a respective set of operating parameters and has a respective width between indices of the set of operating parameters. In these aspects, determining the change in the distribution of the operating parameters includes determining that the width of one or more quantiles of the plurality of quantiles has increased by more than the widths of other quantiles of the plurality of quantiles.

Optionally, operation of the rechargeable battery includes charging of the rechargeable battery. Operation of the rechargeable battery may include discharging of the rechargeable battery.

Yet another aspect of the disclosure provides a vehicle. The vehicle includes a rechargeable battery having a plurality of cells and memory hardware. The memory hardware stores instructions that, when executed on data processing hardware in communication with the memory hardware, cause the data processing hardware to perform operations. The operations include, based on processing of sensor data representative of operation of the rechargeable battery, determining an operating parameter corresponding to each cell of the plurality of cells of the rechargeable battery. During operation of the rechargeable battery, and based on determining a change in a distribution of the operating parameters corresponding to the plurality of cells, the operations include determining a dynamic threshold value. Based on the operating parameter corresponding to one or more cells of the plurality of cells violating the dynamic threshold value, the operations include classifying the one or more cells of the plurality of cells as a faulty cell. The operations include generating an alert representative of the one or more cells of the plurality of cells classified as the faulty cell. This aspect may include one or more of the following optional features.

In some implementations, the sensor data is representative of at least one of a current of the rechargeable battery and respective voltages for each cell of the plurality of cells. In some examples, the operating parameter corresponding to each cell is determined based on an electric circuit model (ECM). The ECM includes at least one resistance value for the cell and at least one capacitance value for the cell.

In some aspects, the distribution of the operating parameters corresponding to the plurality of cells includes a plurality of quantiles. Each quantile of the plurality of quantiles includes a respective set of operating parameters and has a respective width between indices of the set of operating parameters. In these aspects, determining the change in the distribution of the operating parameters includes determining that the width of one or more quantiles of the plurality of quantiles has increased by more than the widths of other quantiles of the plurality of quantiles.

Optionally, operation of the rechargeable battery includes charging of the rechargeable battery. Operation of the rechargeable battery may include discharging of the rechargeable battery.

The details of one or more implementations of the disclosure are set forth in the accompanying drawings and the description below. Other aspects, features, and advantages will be apparent from the description and drawings, and from the claims.

### BRIEF DESCRIPTION OF THE DRAWINGS

The drawings described herein are for illustrative purposes only of selected configurations and are not intended to limit the scope of the present disclosure.

FIG. 1 is a perspective view of a vehicle equipped with a rechargeable battery and a battery fault detection system.

FIG. 2 is a schematic diagram of the battery fault detection system.

FIG. 3 is a schematic diagram of a classification module of the battery fault detection system determining a status for a cell of the battery.

FIG. 4 is a circuit diagram of an electronic circuit model (ECM) used to determine parameter sets for the cells of the battery.

FIG. 5 is an example schematic diagram for an anomaly detection module of the battery fault detection system.

FIG. 6 is a flow diagram for an example method of detecting a faulty cell of the battery.

FIGS. 7A-7C are charts showing parameters for the cells of the battery determined during operation of the battery.

FIG. 7D is a chart showing the determined statuses for the cells of the battery during the operation of FIGS. 7A-7C.

FIG. 8A is a chart showing a parameter for the cells of the battery determined during another operation of the battery.

FIG. 8B is a chart showing the determined statuses for the cells of the battery during the operation of FIG. 8A.

FIG. 8C is a chart showing temperature sensor data for one cell of the battery during the operation of FIG. 8A.

FIGS. 9A-12B are charts showing the distribution of parameters for the cells of the battery during operation of the battery.

Corresponding reference numerals indicate corresponding parts throughout the drawings.

### DETAILED DESCRIPTION

Example configurations will now be described more fully with reference to the accompanying drawings. Example configurations are provided so that this disclosure will be thorough, and will fully convey the scope of the disclosure to those of ordinary skill in the art. Specific details are set forth such as examples of specific components, devices, and methods, to provide a thorough understanding of configurations of the present disclosure. It will be apparent to those of ordinary skill in the art that specific details need not be employed, that example configurations may be embodied in many different forms, and that the specific details and the example configurations should not be construed to limit the scope of the disclosure.

The terminology used herein is for the purpose of describing particular exemplary configurations only and is not intended to be limiting. As used herein, the singular articles “a,” “an,” and “the” may be intended to include the plural forms as well, unless the context clearly indicates otherwise. The terms “comprises,” “comprising,” “including,” and “having,” are inclusive and therefore specify the presence of features, steps, operations, elements, and/or components, but do not preclude the presence or addition of one or more other features, steps, operations, elements, components, and/or groups thereof. The method steps, processes, and operations described herein are not to be construed as necessarily requiring their performance in the particular order discussed or illustrated, unless specifically identified as an order of performance. Additional or alternative steps may be employed.

When an element or layer is referred to as being “on,” “engaged to,” “connected to,” “attached to,” or “coupled to” another element or layer, it may be directly on, engaged, connected, attached, or coupled to the other element or layer, or intervening elements or layers may be present. In contrast, when an element is referred to as being “directly on,” “directly engaged to,” “directly connected to,” “directly attached to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

The terms “first,” “second,” “third,” etc. may be used herein to describe various elements, components, regions, layers and/or sections. These elements, components, regions, layers and/or sections should not be limited by these terms. These terms may be only used to distinguish one element, component, region, layer or section from another region, layer or section. Terms such as “first,” “second,” and other numerical terms do not imply a sequence or order unless clearly indicated by the context. Thus, a first element, component, region, layer or section discussed below could be termed a second element, component, region, layer or section without departing from the teachings of the example configurations.

In some instances, the term “module” may refer to a portion of a battery assembly, such as a grouping of battery cells assembled into a module with multiple modules combined to form the battery assembly. In other instances, including the definitions below, the term “module” may be replaced with the term “circuit.” The term “module” may refer to, be part of, or include an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor (shared, dedicated, or group) that executes code; memory (shared, dedicated, or group) that stores code executed by a processor; other suitable hardware components that provide the described functionality; or a combination of some or all of the above, such as in a system-on-chip.

The term “code,” as used above, may include software, firmware, and/or microcode, and may refer to programs, routines, functions, classes, and/or objects. The term “shared processor” encompasses a single processor that executes some or all code from multiple modules. The term “group processor” encompasses a processor that, in combination with additional processors, executes some or all code from one or more modules. The term “shared memory” encompasses a single memory that stores some or all code from multiple modules. The term “group memory” encompasses a memory that, in combination with additional memories, stores some or all code from one or more modules. The term “memory” may be a subset of the term “computer-readable medium.” The term “computer-readable medium” does not encompass transitory electrical and electromagnetic signals propagating through a medium, and may therefore be considered tangible and non-transitory memory. Non-limiting examples of a non-transitory memory include a tangible computer readable medium including a nonvolatile memory, magnetic storage, and optical storage.

The apparatuses and methods described in this application may be partially or fully implemented by one or more computer programs executed by one or more processors. The computer programs include processor-executable instructions that are stored on at least one non-transitory tangible computer readable medium. The computer programs may also include and/or rely on stored data.

A software application (i.e., a software resource) may refer to computer software that causes a computing device to perform a task. In some examples, a software application may be referred to as an “application,” an “app,” or a “program.” Example applications include, but are not limited to, system diagnostic applications, system management applications, system maintenance applications, word processing applications, spreadsheet applications, messaging applications, media streaming applications, social networking applications, and gaming applications.

The non-transitory memory may be physical devices used to store programs (e.g., sequences of instructions) or data (e.g., program state information) on a temporary or permanent basis for use by a computing device. The non-transitory memory may be volatile and/or non-volatile addressable semiconductor memory. Examples of non-volatile memory include, but are not limited to, flash memory and read-only memory (ROM)/programmable read-only memory (PROM)/erasable programmable read-only memory (EPROM)/electronically erasable programmable read-only memory (EEPROM) (e.g., typically used for firmware, such as boot programs). Examples of volatile memory include, but are not limited to, random access memory (RAM), dynamic random access memory (DRAM), static random access memory (SRAM), phase change memory (PCM) as well as disks or tapes.

These computer programs (also known as programs, software, software applications or code) include machine instructions for a programmable processor, and can be implemented in a high-level procedural and/or object-oriented programming language, and/or in assembly/machine language. As used herein, the terms “machine-readable medium” and “computer-readable medium” refer to any computer program product, non-transitory computer readable medium, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term “machine-readable signal” refers to any signal used to provide machine instructions and/or data to a programmable processor.

Various implementations of the systems and techniques described herein can be realized in digital electronic and/or optical circuitry, integrated circuitry, specially designed ASICs (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

The processes and logic flows described in this specification can be performed by one or more programmable processors, also referred to as data processing hardware, executing one or more computer programs to perform functions by operating on input data and generating output. The processes and logic flows can also be performed by special purpose logic circuitry, e.g., an FPGA (field programmable gate array) or an ASIC (application specific integrated circuit). Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

To provide for interaction with a user, one or more aspects of the disclosure can be implemented on a computer having a display device, e.g., a CRT (cathode ray tube), LCD (liquid crystal display) monitor, or touch screen for displaying information to the user and optionally a keyboard and a pointing device, e.g., a mouse or a trackball, by which the user can provide input to the computer. Other kinds of devices can be used to provide interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

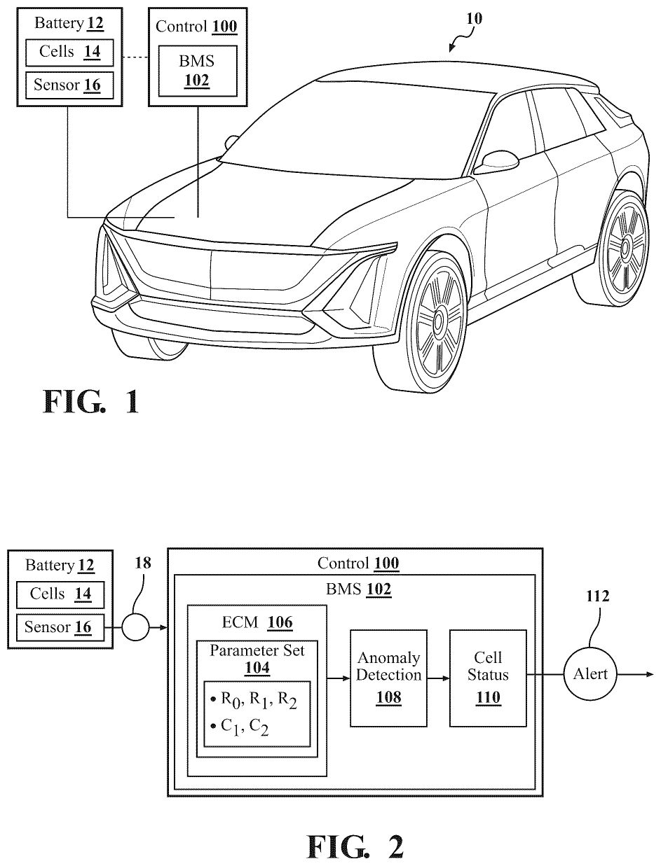

Referring now to the figures and the illustrated configurations depicted therein, a vehicle 10, such as an electric vehicle (EV) or a plug-in hybrid vehicle (PHEV) or a hybrid vehicle, includes a rechargeable battery assembly 12 that at least partially powers a propulsion system of the vehicle 10 (FIG. 1) For example, the battery assembly 12 may include a lithium ion battery assembly, a nickel metal hydride battery assembly, a lithium metal rechargeable battery assembly, a sodium ion battery assembly, a combination of these assemblies into a master assembly, and the like. The vehicle 10 is equipped with an electronic control unit (ECU) 100 or control module having electronic circuitry and associated software for operating a battery fault detection system 102 or a battery management system (BMS) of the vehicle 10. During operation of the rechargeable battery assembly 12, such as during charging of the battery 12 or during discharge of the battery 12 to power the propulsion system of the vehicle 10, the battery fault detection system 102 monitors one or more operating parameters of the battery 12 to detect faults in one or more cells 14 of the battery 12. As discussed further below, the battery fault detection system 102 implements an algorithm that extracts statistical features representative of each cell 14 of the battery 12 and identifies anomalous cells 14 based on comparison of the extracted features to dynamic threshold values. The dynamic threshold values are determined based on operation of the battery 12 over time and thus may be adjusted based on changes in operation of the battery 12 according to the algorithm implemented by the battery fault detection system 102. This allows the battery fault detection system 102 to identify faults in the battery 12 regardless of battery chemistry or predetermined operating parameters, such as temperature of the battery 12, state of charge (SOC) of the battery 12, cycle age of the battery 12, and the like. Thus, although discussed herein as determining the health of the battery 12 of the vehicle 10, it should be understood that characteristics of the battery fault detection system 102 are suitable for use in determining the health of various rechargeable battery systems regardless of chemistry or application.

The battery 12 includes a plurality of cells 14 and one or more sensors 16 that collect sensor data 18 representative of operation of the battery 12 over time. In some examples, cells 14 are first grouped or assembled into modules and a plurality of modules are grouped or assembled to create the battery 12. The one or more sensors 16 may collect sensor data 18 representative of an electrical current of the battery 12 (e.g., in amps), voltage for each cell 14 of the battery 12 and/or voltage for the battery 12 as a whole, temperature at or near the battery 12 (e.g., an environmental temperature at the vehicle 10 generally or an environmental temperature at or near the battery 12), and the like. Sensor data for each cell 14 is collected simultaneously. Because the sensed data points are collected at the same point in time for each cell, each cell 14 has substantially the same SOC, cycle age, and temperature at corresponding data points. The one or more sensors 16 may be disposed at the vehicle 10 and/or integrated with or disposed at the battery 12. Collected sensor data 18 may be transmitted to the control module 100 and processed in real-time to determine the health of the battery 12. That is, the battery fault detection system 102 processes the captured sensor data 18 during operation of the battery 12 to provide an online detection mechanism.

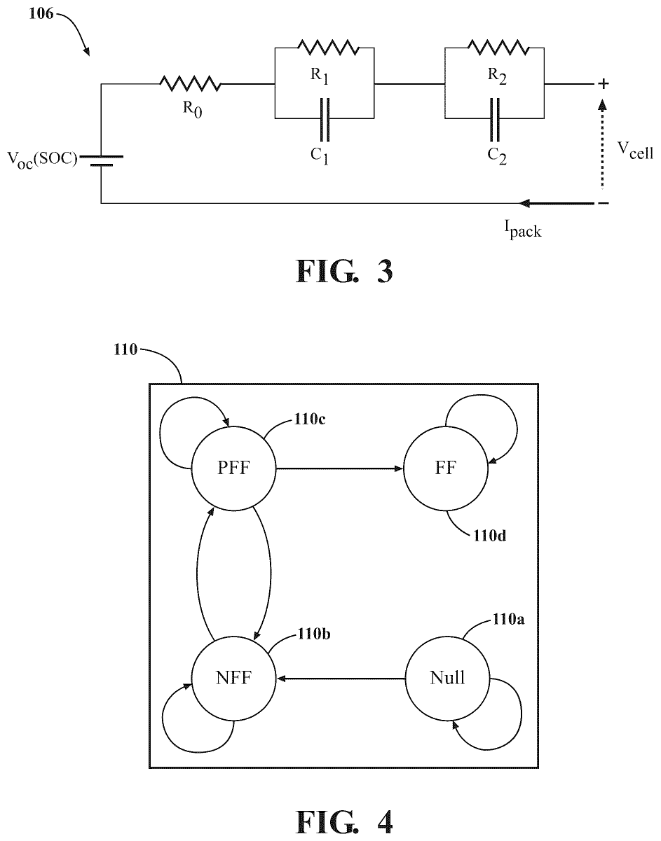

Referring to FIG. 2, the battery fault detection system 102 determines one or more operating parameters or physical characteristics corresponding to each cell 14 of the battery 12 based on the captured sensor data 18. In the illustrated example, the battery fault detection system 102 determines a parameter set 104 including a group of parameters or physical characteristics corresponding to each cell 14 of the battery 12. The captured sensor data 18 and the parameter set 104 for each cell 14 are tracked as a time series for determining health of the battery 12 in real-time during operation of the battery 12. For example, the parameter set 104 may be determined based on an electric circuit model (ECM) that determines characteristic values for the cell, such as resistance values, capacitance values, a SOC value, a current value, and the like. Optionally, the parameter set 104 may include a value representative of the relative health of the cell compared to other cells of the battery, such as a health score or ranking. In the illustrated example, the parameter set 104 is determined based on an ECM 106 that includes respective resistance values for the cell 14 (such as R₀, R₁, and R₂), respective capacitance values for the cell 14 (such as C₁ and C₂), a state of charge value for the cell 14 (V_{OC}), a current value for the battery 12 (I_{pack}), and/or a voltage value for the cell 14 (V_{cell}).

Because each cell 14 of the battery 12 is modeled using the ECM 106 to determine the respective parameter set 104 for the cell 14, the battery fault detection system 102 may adjust processing based on the type of sensor data 18 received. In other words, the system 102 is configured to determine parameter sets 104 representative of the operation of each cell 14 of the battery 12 based on different inputs of sensor data 18 and thus may be utilized in a variety of applications.

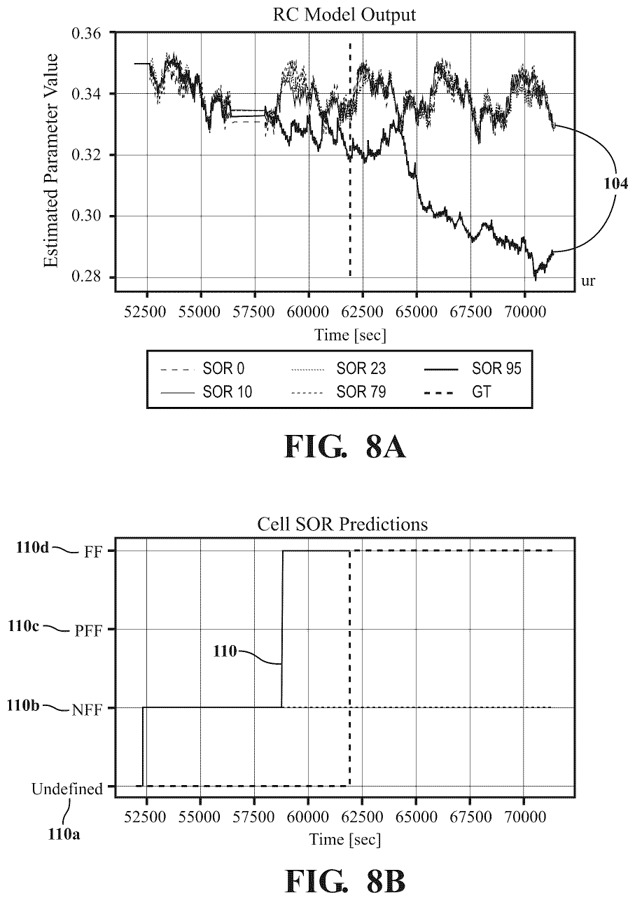

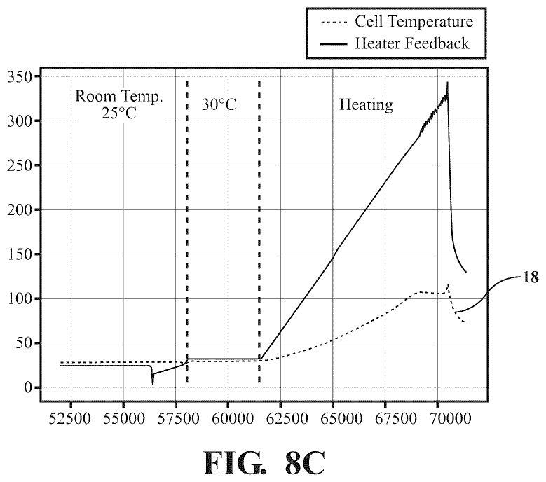

In some examples, an anomaly detection module 108 of the battery fault detection system 102 monitors one or more parameters of the parameter sets 104 (e.g., R₀, R₁, and C₁) for determining a cell status 110 or classification for the cell 14 corresponding to the parameter set 104 (e.g., FIGS. 7A-12B). Optionally, the anomaly detection module 108 of the battery fault detection system 102 may monitor the captured sensor data 18 directly for determining the cell status 110 without first determining parameter sets 104 corresponding to each cell 14.

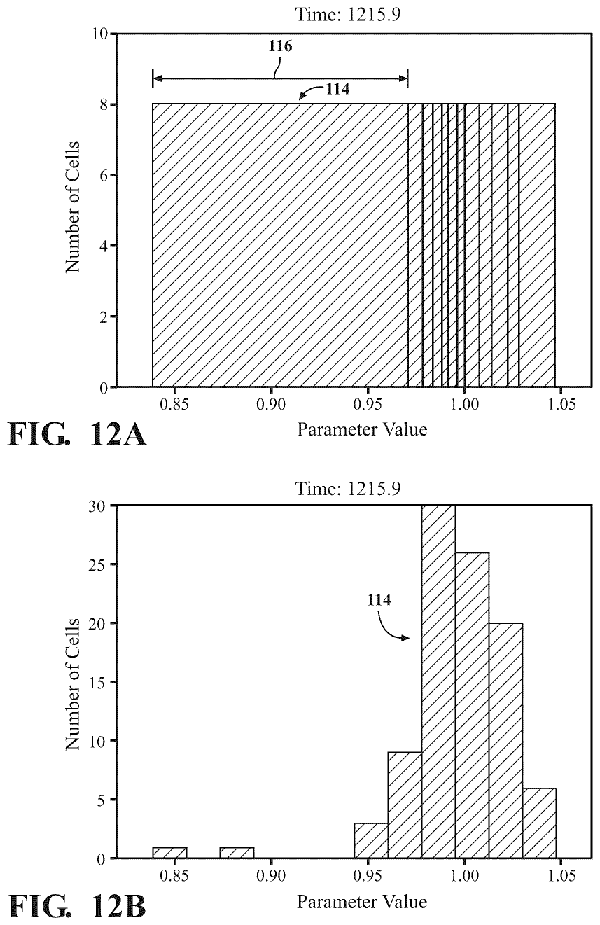

During operation of the battery 12, such as during recharging of the battery 12 or during discharge of the battery 12 to power the propulsion system of the vehicle 10, the anomaly detection module 108 analyzes the parameter sets 104 to determine statistical properties of the determined characteristics across all cells 14 of the battery 12. In other words, the anomaly detection module 108 may determine distributions of the parameter sets 104 (e.g., a distribution of at least one parameter of the parameter sets 104 or a distribution of at least one signal from the captured sensor data 18) (e.g., FIGS. 9A-12B) and the cell status 110 is determined based on the statistical distribution of the parameter sets 104.

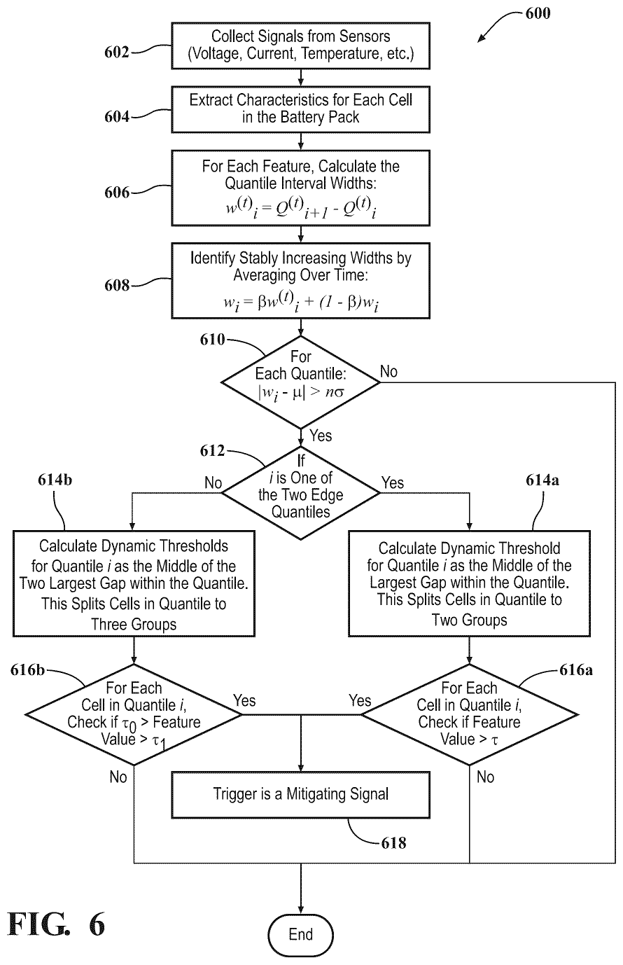

As shown in FIG. 4, the status 110 of each cell 14 may be initialized at an undefined state 110a or null state upon vehicle startup. This is to decrease the impact of any artifacts that may occur at the beginning of run time. That is, this may avoid false fault detection as operation of the battery 12 normalizes during early stages of operation of the vehicle 10. After a threshold period of time, the status 110 of each cell 14 may be transitioned to a no fault found (NFF) state 110b. The threshold period of time may define a predetermined amount of time (such as 30 seconds, 60 seconds, 90 seconds and the like) that must pass from vehicle startup before the statuses 110 of the cells 14 are transitioned from the null state 110a to the NFF state 110b. From the NFF state 110b, the status 110 of the cell 14 may be transitioned to a probable fault found (PFF) state 110c based on first and second order statistical properties of the distribution of the parameter sets 104. In other words, based on variance of a cell's parameter set 104 relative to other cell's parameter sets 104 being statistically significant, the status 110 of the cell 14 is adjusted to a PFF state 110c. This state 110 can change for every time sample. From the PFF state 110c, the status 110 of the cell 14 may be adjusted to a fault found (FF) state 110d, such as based on the state 110 of the cell 14 being at the PFF state 110c for greater than a threshold period of time. In other words, the state 110 of the cell 14 may not be transitioned to the FF state 110d immediately upon determination of the PFF state 110c (i.e., upon the first instance of determining the PFF state 110c), but rather the state 110 of the cell 14 may be transitioned to the FF state 110d after an additional condition is met (e.g., a predetermined period of time has passed with the state 110 of the cell 14 in the PFF state 110c, a predetermined ratio of time spent in the PFF state 110c, and the like). The FF state 110d is a terminal state, meaning that once a cell 14 transitions from the PFF state 110c to the FF state 110d, it will remain in the FF state 110d.

An alert 112 is generated based on one or more cells 14 being classified as a faulty cell (e.g., based on at least one parameter set 104 indicative of the PFF state 110c and/or the FF state 110d). The alert 112 may include a signal or message broadcast to the driver of the vehicle 10, such as an audio tone or message played in the interior cabin of the vehicle 10, an illuminated icon or message displayed at the gauge cluster or infotainment screen of the vehicle 10, or a signal communicated to a user device associated with the driver of the vehicle 10. Further, the alert 112 may be communicated exterior of the vehicle 10, such as by illuminating or flashing exterior lights of the vehicle 10 and/or by activating a horn of the vehicle 10. Optionally, the alert 112 may be communicated to a controller of the vehicle 10 to cause the vehicle 10 to shut down or cease operation of the battery 12.

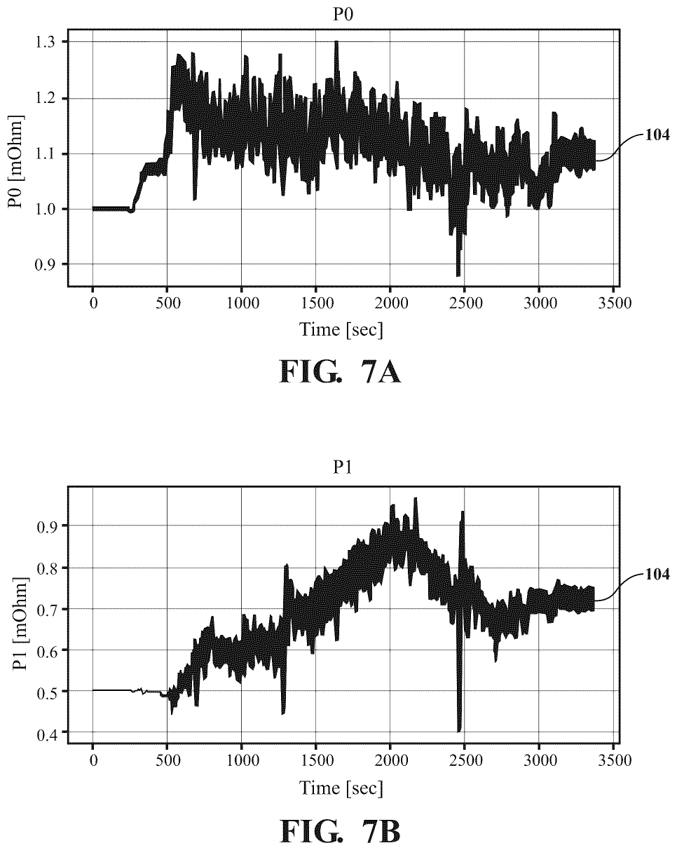

As shown in FIG. 5, the anomaly detection module 108 may thus receive the parameter set 104 containing parameter values corresponding to respective cells 14 of the battery 12 at respective time stamps. The parameter set 104 may be determined based on captured sensor data 18 together with the ECM 106. For each time interval, the parameter values of the parameter set 104 are arranged into quantiles 114 across a distribution. Based on detecting change in the parameter distribution, the anomaly detection module 108 applies a mechanism to detect faulty cells using a dynamic threshold. As discussed further below, the dynamic threshold is adjusted or changed or set during operation of the battery 12 based on detecting changes in the distribution of the parameter set 104 over time. The dynamic threshold is determined as a value in the parameter set 104 so that parameter values in the parameter set 104 that violate the dynamic threshold (i.e., that are greater than a maximum dynamic threshold value and/or less than a minimum dynamic threshold value) are identified as corresponding to anomalous cells. A dynamic or changing or adjustable threshold value is used to account for changes in battery performance that may affect substantially all cells 14 of the battery 12 (e.g., an environmental temperature change) and thus result in a shift of the parameter distribution that does not necessarily indicate an anomalous cell.

That is, anomalous cells cause the parameter distribution to transform in a manner that may not shift the distribution. For example, the effect of anomalous cells on the parameter set 104 may cause the distribution to disperse, or a distribution that is initially Gaussian and then evolves into a uniform distribution could indicate a developing fault. The dynamic threshold may thus be determined or set based on changes in the parameter distribution so that anomalous cells are identified by determining transformations that are invariant to shifts, such as by detecting low-density areas of the parameter distribution. The parameter set 104 may thus be compared to the dynamic threshold and the classification 110 of the cells 14 may be updated and the alert 112 generated responsive to classifying one or more cells 14 as faulty cells.

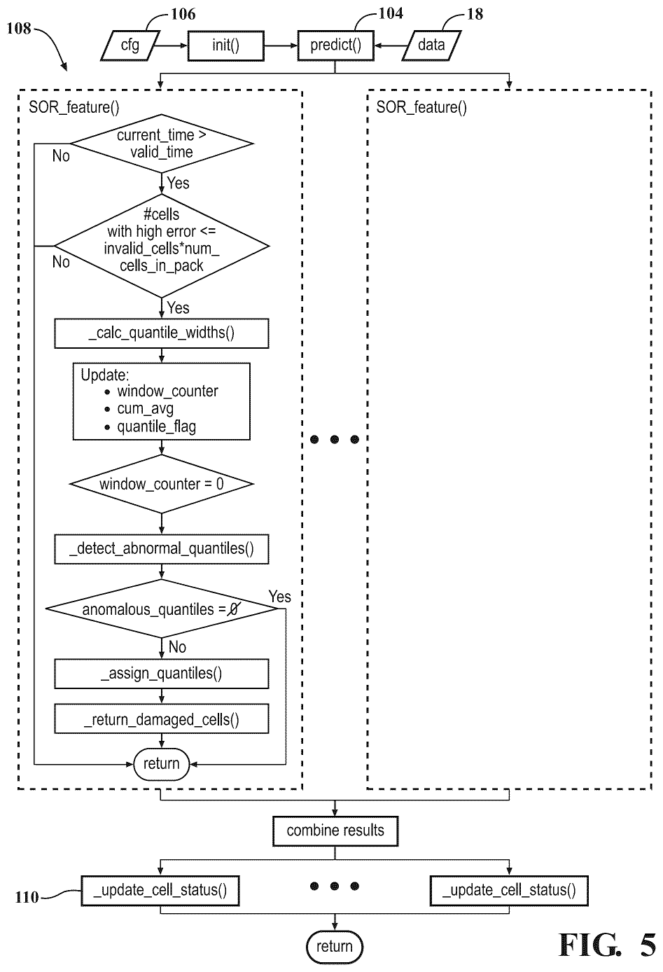

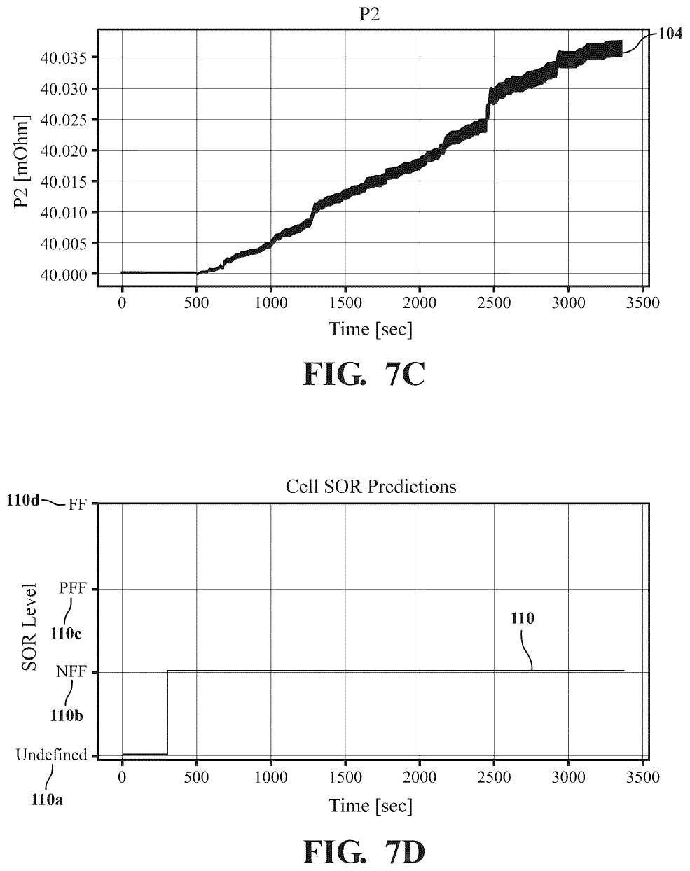

Determination of the status 110 of one or more cells 14 of the battery 12 and the illustrated configurations of FIGS. 1-5 will be discussed in relation to the method 600 of FIG. 6. FIG. 6 provides a flowchart of an exemplary arrangement of operations for a method 600 of determining changes in the distribution of the parameter sets 104, determining a dynamic threshold value for the parameter sets 104 and determining the status 110 of one or more cells 14 of the battery 12 based on whether the corresponding parameter set 104 violates the dynamic threshold.

At operation 602, the method 600 includes collecting signals or sensor data 18 from sensors 16 at the battery 12 and/or vehicle 10. The captured sensor data 18 may include voltage of the battery 12 and/or voltage of the cells 14 of the battery 12, current of the battery 12, temperature at or near the battery 12, and the like. At operation 604, the method 600 includes extracting characteristics or parameter sets 104 for each cell 14 of the battery 12. For example, the parameter sets 104 are determined based on the ECM 106.

At operation 606, the method 600 includes calculating quantile interval widths for the distribution of each characteristic of the parameter set 104. That is, the distribution is divided or separated into a plurality of quantiles 114 (such as 12 quantiles) (e.g., FIGS. 9A-12B). Each quantile 114 includes a respective set of parameter values corresponding to respective cells 14 of the battery 12. The quantiles 114 have respective widths 116 that may be measured as the difference between the largest parameter of consecutive sets. Optionally, the widths 116 may be measured as the difference between the smallest parameter of consecutive sets. The bounds of the quantiles 114 define the quantile indices. For example, for a battery 12 that includes 96 cells 14 sorted and indexed 0 to 95, the widths 116 may be measured as the difference between the parameter values at indexes (0, 7, 15, 23, 31, 39, 47, 55, 63, 71, 79, 87, 95). The edge case of the first or last quantile 114 may be determined as the difference between a largest parameter value of the quantile 114 and a smallest parameter value of the quantile 114. For each quantile 114 (i) at a point in time (t), the quantile interval width 116 (wᵢ) between adjacent quantile indices (Qᵢ₊₁, Qᵢ) may be calculated by:

$${w}_{i}^{( t )} = {Q}_{i + 1}^{( t )} - {Q}_{i}^{( t )}$$

At operation 608, the method 600 includes identifying stably increasing widths 116 by averaging the widths 116 for respective quantiles 114 over time. Using a weight (β) for weighted average of quantile widths 116, the average quantile width 116 may be calculated by:

$${w}_{i} = β {w}_{i}^{( t )} + ( 1 - β ) {w}_{i}$$

At operation 610, the method 600 includes determining whether the width 116 of one or more quantiles 114 has increased by more than a threshold amount or by relatively more than the widths 116 of other quantiles 114. In the illustrated example, this is done by determining whether a difference between the weighted average quantile width (wᵢ) and a cumulative average (μ) for each quantile 114 with a vector of length being the number of quantiles 114 is greater than the product of an estimate of cumulative standard deviations (σ) for each quantile 114 with a vector of length being the number of quantiles 114 and a number of standard deviations (n). The number of standard deviations may be a configurable parameter and may be set to equal three. For example, the number of standard deviations may be a preset value based on battery performance tolerances, or an adjustable value (e.g., adjustable by the vehicle manufacturer, adjustable by a vehicle technician, and the like). Operation 610 may be represented by:

$$\vert {w}_{i} - μ \vert > n σ$$

Based on determining that the width 116 of the quantile 114 is indicative of the parameter values in the quantile 114 corresponding to one or more faulty cells, the method 600 includes at operation 612 determining if the offending quantile 114 is one of the edge quantiles 114 in the distribution. For example, and as shown in FIGS. 9A-12B, the edge quantiles 114 are the outermost quantiles 114 in the distribution containing either the smallest set of parameter values or the largest set of parameter values as compared to intermediate quantiles 114 or middle quantiles 114 that are between the edge quantiles 114. To determine which parameter values in the quantile 114 correspond to faulty cells, the system 102 determines a dynamic threshold value and compares the parameter values in the quantile 114 to the dynamic threshold value.

For example, based on determining that the width 116 of an edge quantile 114 has increased by relatively more than the widths 116 of other quantiles 114, the method 600 includes at operation 614a setting the dynamic threshold value (τ) within the quantile 114 as one of an intra-set threshold value or intra-quantile threshold value and an inter-set threshold value or inter-quantile threshold value. The intra-quantile threshold value is used when a gap between a pair of adjacent parameter values within the quantile 114 is larger than the gap between parameter values of the edge quantile 114 and the adjacent quantile 114. The intra-quantile threshold value is determined as the middle of the largest gap within the quantile 114 so that the quantile 114 is split into two groups. That is, the intra-quantile threshold value is between a pair of adjacent parameter values of the set of parameter values in the quantile 114 where the pair of adjacent parameter values have the largest difference between them compared to other pairs of adjacent parameter values. The inter-quantile threshold value is used when the gap between adjacent parameter values of the edge quantile 114 and its adjacent quantile 114 is larger than the largest gap between pairs of adjacent parameter values within the quantile 114. The inter-quantile threshold value is the middle of the gap between the adjacent parameter values of the edge quantile 114 and its adjacent quantile 114. Thus, at operation 616a, the method 600 includes determining which parameter values in the quantile 114 correspond to faulty cells by determining if the parameter value is greater than (τ).

Based on determining that the width 116 of a middle quantile 114 has increased by relatively more than the widths 116 of other quantiles 114, the method 600 includes at operation 614b setting the dynamic threshold value within the quantile 114 as the middle of the two largest gaps within the quantile 114 so that the quantile 114 is split into three groups. In other words, one dynamic threshold value (to) is set between a first pair of adjacent parameter values that have the largest difference between them compared to other pairs of adjacent parameter values in the quantile 114, and another dynamic threshold value (11) is set between a second pair of adjacent parameter values that have the second largest difference between them compared to other pairs of adjacent parameter values in the quantile 114. At operation 616b, the method 600 includes determining which parameter values in the quantile 114 correspond to faulty cells by determining if the parameter value is greater than (τ₁) and less than (τ₀). At operation 618, the method 600 includes generating the alert 112 based on determining that at least one cell 14 of the battery 12 is classified as a faulty cell.

By way of example, FIGS. 7A-7D represent operation of the battery fault detection system 102 during operation of the battery 12 where no fault was found and no cells 14 of the battery 12 were classified as faulty cells. As shown in FIGS. 7A-7C, parameter values (P₀, P₁, and P₂) of the parameter set 104 are tracked over time. Specifically, resistance values and capacitance values of the ECM 106 may be determined and correspond to each cell 14 of the battery 12. Because the parameter values change relatively equal to one another across the cells 14, the status 110 of the cells in FIG. 7D remains in the NFF state 110b throughout operation of the battery 12. In other words, the parameter set 114 of the battery cells 14 may vary during operation of the battery 12 without triggering an alert 112 based on the parameter set 114 for each battery cell 14 varying to a relatively equal degree.

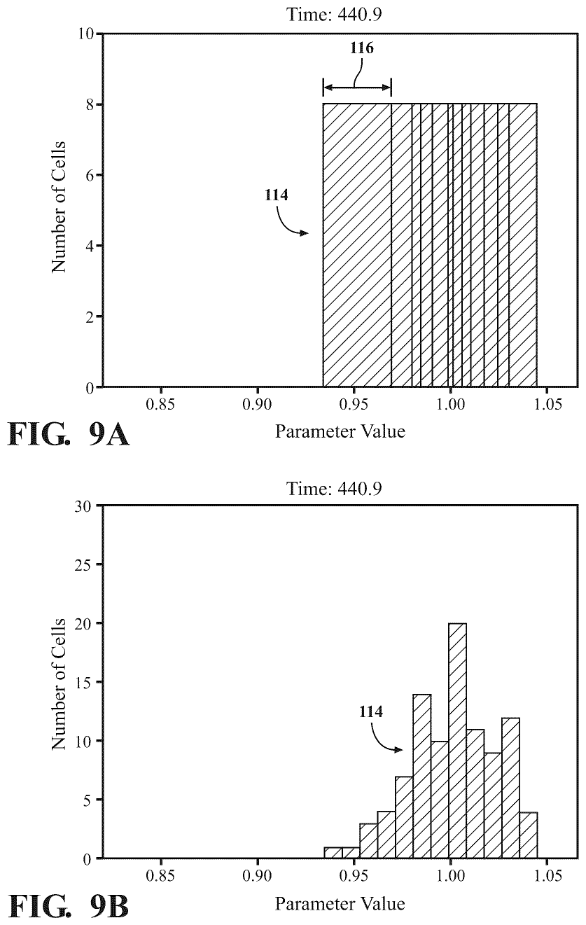

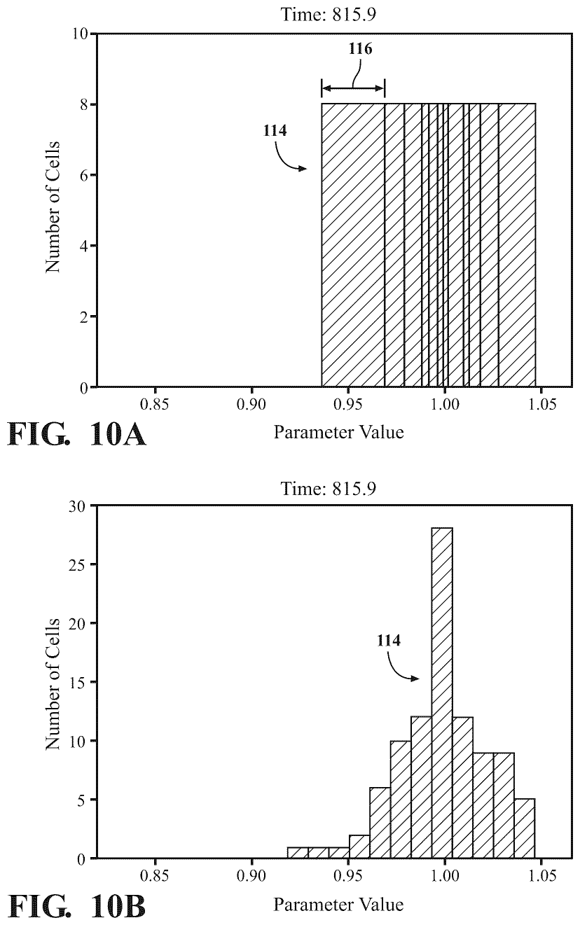

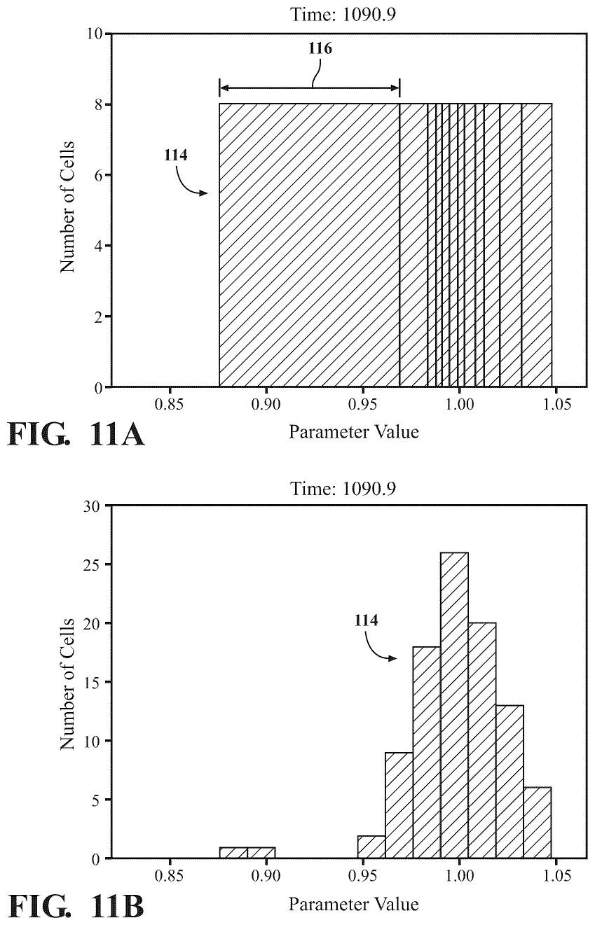

FIG. 8A-8C represent operation of the battery fault detection system 102 during operation of the battery 12 where one or more cells 14 were classified as faulty cells. As shown in FIG. 8C, captured sensor data 18 during operation of the battery 12 is indicative of a temperature increase of one cell 14 of the battery 12 at a time of about 62,000 seconds. In FIG. 8A, this temperature increase corresponds to a decrease in the parameter value for the parameter set 114 of the corresponding cell 14. Because the parameter value for the parameter set 114 of the heated cell 14 fluctuates to a different degree from the parameter values for the parameter sets of the other cells 14 of the battery 12, the battery fault detection system 102 is able to detect the fault in the cell 14 and adjust the status 110 of the cell 14 to a FF status 110d while maintaining the status 110 of other cells 14 at a NFF status 110b (FIG. 8B).

FIGS. 9A-12B represent changes in the distribution of parameter values in the parameter sets 104 corresponding to the cells 14 of the battery 12 during operation of the battery 12. As shown in FIGS. 9A and 9B, the quantiles 114 may have relatively equal widths 116, with the parameter values 104 relatively evenly distributed about the value 1.00 at an operating time of about 440.9 seconds. As operation of the battery 12 continues to an operating time of about 815.9 seconds, operation of the cells 14 may normalize and thus consolidate the parameter values about the value 1.00 (FIGS. 10A and 10B). That is, a larger number of cells 14 may have corresponding parameter values at or near 1.00 and thus the width 116 of the quantiles 114 at or near 1.00 may be narrower than at the time stamp of FIGS. 9A and 9B.

As respective cells 14 of the battery 12 begin exhibiting faulty performance, the width 116 of quantiles 114 containing parameter values corresponding to the faulty cells 14 may begin to grow. For example, and as shown in FIGS. 11A and 11B at an operating time of about 1,090.9 seconds, two cells 14 have operating parameter values of about 0.90 or less while a majority of cells 14 continue to have operating parameter values at or near 1.00. This causes the lower edge quantile 114 to have a significantly larger width 116 compared to the widths 116 of the other quantiles 114 in the distribution. Thus, the anomaly detection module 108 may classify these cells 14 as faulty cells. Similarly, and as shown in FIGS. 12A and 12B at an operating time of about 1,215.9 seconds, as the parameter values for faulty cells 14 continues to decrease (to respective values of about 0.85 and 0.88) and the parameter values for other cells 14 remains at or near 1.00, the width 116 of the associated quantile 114 increases.

Thus, the battery fault detection system 102 is configured to calculate cell parameter statistics and adaptively detect faulty cells 14 over the entire battery 12. Instead of relying solely on sensed signals such as voltage, current and temperature, the system 102 calculates operating parameter sets 104 that accommodate physical characteristics and environmental factors. This emphasizes consideration of cell properties within the battery 12 without making assumptions of individual cell characteristics. This broader perspective may provide a more holistic approach of understanding battery performance. Further, the system 102 may dynamically adjust to various environmental scenarios and battery loads. For example, when environmental factors affect the operation across the battery 12 evenly, the parameter values 104 corresponding to the cells 14 of the battery 12 may be affected relatively equally and will thus not trigger a warning or indicate a faulty cell. Further, because faulty cells are statistical outliers, the system 102 may detect faulty cells before operation of the battery 12 is significantly affected.

A number of implementations have been described. Nevertheless, it will be understood that various modifications may be made without departing from the spirit and scope of the disclosure. Accordingly, other implementations are within the scope of the following claims.

The foregoing description has been provided for purposes of illustration and description. It is not intended to be exhaustive or to limit the disclosure. Individual elements or features of a particular configuration are generally not limited to that particular configuration, but, where applicable, are interchangeable and can be used in a selected configuration, even if not specifically shown or described. The same may also be varied in many ways. Such variations are not to be regarded as a departure from the disclosure, and all such modifications are intended to be included within the scope of the disclosure.

What is claimed is:

1. A computer-implemented method when executed on data processing hardware causes the data processing hardware to perform operations comprising:
based on processing of sensor data representative of operation of a rechargeable battery, determining an operating parameter corresponding to each cell of a plurality of cells of the rechargeable battery;
during operation of the rechargeable battery, and based on determining a change in a distribution of the operating parameters corresponding to the plurality of cells, determining a dynamic threshold value;
based on the operating parameter corresponding to one or more cells of the plurality of cells violating the dynamic threshold value, classifying the one or more cells of the plurality of cells as a faulty cell; and
generating an alert representative of the one or more cells of the plurality of cells classified as the faulty cell.

2. The method of claim 1, wherein the sensor data is representative of at least one selected from the group consisting of (i) a current of the rechargeable battery and (ii) respective voltages for each cell of the plurality of cells.

3. The method of claim 1, wherein the operating parameter corresponding to each cell is determined based on an electric circuit model (ECM).

4. The method of claim 3, wherein the ECM includes (i) at least one resistance value for the cell and (ii) at least one capacitance value for the cell.

5. The method of claim 1, wherein:
the distribution of the operating parameters corresponding to the plurality of cells includes a plurality of quantiles, each quantile of the plurality of quantiles including a respective set of operating parameters and having a respective width between indices of the set of operating parameters; and
determining the change in the distribution of the operating parameters includes determining that the width of one or more quantiles of the plurality of quantiles has increased by more than the widths of other quantiles of the plurality of quantiles.

6. The method of claim 5, wherein, based on determining that the width of an edge quantile of the plurality of quantiles has increased by more than the widths of other quantiles of the plurality of quantiles, the dynamic threshold value is one selected from the group consisting of (i) an intra-quantile threshold value between a pair of adjacent operating parameters of the set of parameters within the edge quantile that have the largest difference compared to other pairs of adjacent operating parameters of the set of parameters within the edge quantile and (ii) an inter-quantile threshold value between adjacent operating parameters of the set of parameters within the edge quantile and the set of parameters within an adjacent quantile adjacent to the edge quantile.

7. The method of claim 5, wherein, based on determining that the width of an intermediate quantile of the plurality of quantiles has increased by more than the widths of other quantiles of the plurality of quantiles, the dynamic threshold value includes (i) a first value between a first pair of adjacent operating parameters of the set of parameters that have the largest difference compared to other pairs of adjacent operating parameters of the set of parameters and (ii) a second value between a second pair of adjacent operating parameters of the set of parameters that have the second largest difference compared to other pairs of adjacent operating parameters of the set of parameters.

8. The method of claim 1, wherein operation of the rechargeable battery includes at least one selected from the group consisting of (i) charging of the rechargeable battery and (ii) discharging of the rechargeable battery.

9. The method of claim 1, wherein the rechargeable battery is a lithium-ion battery.

10. The method of claim 1, wherein the rechargeable battery is equipped at a vehicle.

11. A system comprising:
memory hardware storing instructions that, when executed on data processing hardware in communication with the memory hardware, cause the data processing hardware to perform operations comprising:
based on processing of sensor data representative of operation of a rechargeable battery, determining an operating parameter corresponding to each cell of a plurality of cells of the rechargeable battery;
during operation of the rechargeable battery, and based on determining a change in a distribution of the operating parameters corresponding to the plurality of cells, determining a dynamic threshold value;
based on the operating parameter corresponding to one or more cells of the plurality of cells violating the dynamic threshold value, classifying the one or more cells of the plurality of cells as a faulty cell; and
generating an alert representative of the one or more cells of the plurality of cells classified as the faulty cell.

12. The system of claim 11, wherein the sensor data is representative of at least one selected from the group consisting of (i) a current of the rechargeable battery and (ii) respective voltages for each cell of the plurality of cells.

13. The system of claim 11, wherein the operating parameter corresponding to each cell is determined based on an electric circuit model (ECM), the ECM including (i) at least one resistance value for the cell and (ii) at least one capacitance value for the cell.

14. The system of claim 11, wherein:
the distribution of the operating parameters corresponding to the plurality of cells includes a plurality of quantiles, each quantile of the plurality of quantiles including a respective set of operating parameters and having a respective width between indices of the set of operating parameters; and
determining the change in the distribution of the operating parameters includes determining that the width of one or more quantiles of the plurality of quantiles has increased by more than the widths of other quantiles of the plurality of quantiles.

15. The system of claim 11, wherein operation of the rechargeable battery includes at least one selected from the group consisting of (i) charging of the rechargeable battery and (ii) discharging of the rechargeable battery.

16. A vehicle comprising:
a rechargeable battery having a plurality of cells; and
memory hardware storing instructions that, when executed on data processing hardware in communication with the memory hardware, cause the data processing hardware to perform operations comprising:
based on processing of sensor data representative of operation of the rechargeable battery, determining an operating parameter corresponding to each cell of the plurality of cells of the rechargeable battery;
during operation of the rechargeable battery, and based on determining a change in a distribution of the operating parameters corresponding to the plurality of cells, determining a dynamic threshold value;
based on the operating parameter corresponding to one or more cells of the plurality of cells violating the dynamic threshold value, classifying the one or more cells of the plurality of cells as a faulty cell; and
generating an alert representative of the one or more cells of the plurality of cells classified as the faulty cell.

17. The vehicle of claim 16, wherein the sensor data is representative of at least one selected from the group consisting of (i) a current of the rechargeable battery and (ii) respective voltages for each cell of the plurality of cells.

18. The vehicle of claim 16, wherein the operating parameter corresponding to each cell is determined based on an electric circuit model (ECM), the ECM including (i) at least one resistance value for the cell and (ii) at least one capacitance value for the cell.

19. The vehicle of claim 16, wherein:
the distribution of the operating parameters corresponding to the plurality of cells includes a plurality of quantiles, each quantile of the plurality of quantiles including a respective set of operating parameters and having a respective width between indices of the set of operating parameters; and
determining the change in the distribution of the operating parameters includes determining that the width of one or more quantiles of the plurality of quantiles has increased by more than the widths of other quantiles of the plurality of quantiles.

20. The vehicle of claim 16, wherein operation of the rechargeable battery includes at least one selected from the group consisting of (i) charging of the rechargeable battery and (ii) discharging of the rechargeable battery.
